(19) United States
(12) Patent Application Publication
(10) Pub. No.: US 2023/0288447 A1
(43) Pub. Date: Sep. 14, 2023

(54) CONTACT PROBE FOR A PROBE HEAD

(71) Applicant: TECHNOPROBE S.P.A., Cernusco Lombardone (LC) (IT)

(72) Inventors: Stefano FELICI, San Jose, CA (US); Fabio MORGANA, Cernusco Lombardone (LC) (IT); Roberto CRIPPA, Cernusco Lombardone (LC) (IT)

(73) Assignee: TECHNOPROBE S.P.A., Cernusco Lombardone (LC) (IT)

(21) Appl. No.: 18/005,880

(22) PCT Filed: Jul. 8, 2021
(86) PCT No.: PCT/EP2021/068939

§ 371 Date: Jan. 18, 2023

(30) Foreign Application Priority Data
Jul. 20, 2020 (IT) 102020000017539

(51) Int. Cl. G01R 1/067; H01R 13/24

(52) U.S. Cl. CPC G01R 1/06738; G01R 1/06761; H01R 13/2492

(57) ABSTRACT

A contact probe for a probe head for test equipment of electronic devices is provided. The contact probe includes a first end portion and a second end portion configured to realize a contact with suitable contact structures, and a body portion extended along a longitudinal development axis between respective the first and second end portions. The first end portion includes a base portion, a peripherally protruding element protruding from the base portion, and a hollow part having a base at a surface of the base portion and being surrounded by the peripherally protruding element. In addition, the peripherally protruding element is configured to penetrate into the contact structures.

### TECHNICAL FIELD

The present invention relates to a contact probe for a probe head.

The invention relates in particular, but not exclusively, to a contact probe for a probe head for a testing apparatus of electronic devices integrated on a wafer and the following description is made with reference to this field of application with the sole aim of simplifying the description thereof.

### BACKGROUND ART

As it is well known, a probe head is essentially a device configured to electrically connect a plurality of contact pads of a microstructure, in particular an electronic device that is integrated on a wafer, with corresponding channels of a test equipment that performs the functionality testing thereof, in particular electric, or generically the test.

The test, which is performed on integrated devices, is particularly useful for detecting and isolating defective devices as early as in the production phase. Usually, probe heads are therefore used for the electric test of devices integrated on a wafer before cutting and assembling them inside a chip containment package.

A probe head usually comprises a high number of contact elements or contact probes formed by wires of special alloys with good electric and mechanical properties and provided with at least one contact portion for a corresponding plurality of contact pads of a device under test.

A probe head of the type commonly called “vertical probe head” essentially comprises a plurality of contact probes held by at least one pair of plates or guides which are substantially plate-shaped and parallel to each other. Said guides are equipped with suitable guide holes and are arranged at a certain distance from each other in order to leave a free space or air gap for the movement and possible deformation of the contact probes. The pair of guides comprises in particular an upper guide and a lower guide, both provided with respective guide holes within which the contact probes axially slide.

The good connection between the contact probes of the probe head and the contact pads of the device under test is ensured by the pressure of the probe head on the device itself, the contact probes, which are movable within the guide holes formed in the upper and lower guides, undergoing, during said pressing contact, a bending inside the air gap between the two guides and a sliding inside said guide holes.

Furthermore, the bending of the contact probes in the air gap may be facilitated through a suitable configuration of the probes themselves or of the guides thereof, as schematically illustrated in FIG. 1, where, for the sake of simplicity of illustration, only one contact probe of the plurality of probes usually comprised in a probe head has been illustrated, the probe head illustrated being of the so-called type “shifted plates probe head”.

In particular, the probe head 10 illustrated in FIG. 1 comprises at least one upper plate or guide 12 and a lower plate or guide 13, having respective upper guide holes 12A and lower guide holes 13A within which at least one contact probe 1 slides.

The contact probe 1 has at least one contact end or tip 1A. The terms end or tip indicates herein and in the following an end portion, which is not necessarily pointed. In particular the contact tip 1A abuts onto a contact pad 15A of a device under test 15 that is integrated on a semiconductor wafer 15′, realizing the mechanical and electric contact between the device under test and a testing apparatus (not represented) which said probe head is an end element of.

In some cases, the contact probes are fixedly fastened to the probe head itself at the upper guide: such probe heads are referred to as “blocked probe heads”.

Alternatively, the contact probes may not be fixedly fastened inside the probe head but held interfaced to a board through a microcontact board: such probe heads are referred to as “unblocked probe heads”. The micro-contact board is usually called “space transformer” since, besides contacting the probes, it also allows spatially redistributing the contact pads realized thereon with respect to the contact pads on the device under test, being tied to the manufacturing technology, in particular relaxing the distance constraints between the centers of the pads themselves.

In this case, as illustrated in FIG. 1, the contact probe 1 has a further contact tip 1B, usually indicated as contact head, towards a plurality of contact pads 16A of said space transformer 16. The proper electric connection between probes and space transformer is analogously ensured to the contact with the device under test by the pressure of the contact heads 1B of the contact probes 1 onto the contact pads 16A of the space transformer 16.

As already explained, the upper guide 12 and lower guide 13 are suitably spaced apart by an air gap 17 which allows the contact probes 1 to deform and allows the contact of contact tip and contact head of the contact probes 1 with the contact pads of the device under test 15 and of the space transformer 16, respectively. The material that makes the contact probe 1 is selected so as to give the probe the needed elasticity and to allow the elastic deformation, also indicated as bending, during the testing.

In some applications, the testing of integrated devices is not carried out on substantially planar structures, such as the contact pads, but at three-dimensional contact structures, in the shape of balls of conductive material, indicated as bumps, or metal cylinders, in particular of copper, indicated as pillars, which protrude from a surface of the device under test.

In this case, specific contact probes, usually indicated as pogo pin and schematically illustrated in FIG. 2, are preferably used.

A pogo pin 20 essentially comprises a body 20C in the shape of a cylinder extended according to a longitudinal development axis of the pogo pin 20, corresponding to the z axis of the local reference of FIG. 2, from whose ends two end portions, indicated, similarly to before, as contact tip 20A and contact head 20B of the pogo pin 20, extend. As previously, the contact tip 20A is configured to abut onto a device under test, in particular at a bump or a pillar of said device, whereas the contact head 20B is configured to abut onto a board that realizes the contact with a testing apparatus.

Suitably, the body 20C of the pogo pin 20 comprises at least one housing 25A for a spring element 25 connected to the contact tip 20A, that is formed at an opening 20D of the body 20C of the pogo pin 20 and is able to move inside said body 20C further to a thrust exerted thereonto by the device under test during the testing, during the pressing contact of the contact tip 20A on a bump or a pillar of said device under test.

To ensure a proper electric connection between the pogo pin and the three-dimensional contact structures of the device under test, in particular bumps and pillars, it is known to make an end portion 22 of the contact tip 20A of the pogo pin 20 so as to have one or more protruding elements, such as a plurality of spikes, as schematically illustrated in FIG. 2. Shapes of this type are usually indicated as “crown shapes” and are made to ensure a partial penetration of the contact tip 20A of the pogo pin 20 inside the material of the three-dimensional contact structures, such as bumps or pillars, so as to improve the desired electric contact with said elements.

Other shapes, more or less complex, are used to make the end portion 22, still with the purpose of ensuring a partial penetration thereof into the material of the three-dimensional contact structures, such as bumps and pillars. It is also possible to also use the pogo pins for the contact with contact pads of devices under test, such as for instance in the case it should be appropriate to ensure a penetration of the contact tip 20A into layers of oxides or anyway dirt that may form superficially on these pads and thus ensure the proper contact between the end portion 22 of the contact tip 20A of the pogo pin 20 and the contact pad of the device under test, indeed.

These particular shapes of the contact tips of the pogo pin, as well as the operation mechanism by penetration into the material of the three-dimensional contact structures or the layer that coats the contact pads however favour the retention of material by the end portion of said pogo pins, which thus need regular and frequent cleaning operations, which—as well known—are usually carried out by touch on abrasive cloths and lead to a partial consumption of the materials in contact with the abrasive cloth, i.e. of said end portions of the contact tips of the pogo pins.

However, the number of these cleaning operations which a pogo pin may be subjected to before a serious deterioration of its performances is very limited. Indeed, the particular shapes used for the contact tip, i.e. the presence of one or more elements, such as a plurality of spikes, able to penetrate into the material making the three-dimensional contact structures or covering the contact pads, do not have a constant section along the longitudinal development axis z of the pogo pin and lose their effectiveness as quickly as the touch on abrasive cloth slowly consumes them.

These particular shapes of the end portion of the contact tips of the pogo pins, which have a non-constant section along the z axis, sometimes lead to uneven contact with the contact three-dimensional structures or with the contact pads, which, since the first operation, may affect the proper electrical connection between pogo pins and device under test.

The technical problem of the present invention is to provide a contact probe having at least one end portion at its contact tip, which has a shape able to ensure the penetration thereof into the material making three-dimensional contact elements or layers coating contact pads of a device under test and able to withstand numerous cleaning operations, in constant performances, so as to overcome the limitations and drawbacks still affecting the contact probes made according to the prior art.

### DISCLOSURE OF INVENTION

The solution idea underlying the present invention is to provide a contact probe having a contact tip equipped with at least one peripherally protruding element with respect to a base portion thereof, so as to define at least one hollow part in said contact tip and allow a facilitated penetration of said contact tip into contact structures of a device under test, such as three-dimensional structures like bumps or pillars, or planar structures such as pads possibly covered by surface layers of oxides or dirt.

Based on this solution idea, the above technical problem is solved by a contact probe for a probe head for a testing apparatus of electronic devices comprising a body portion extended along a longitudinal development axis between respective end portions configured to realize a contact with suitable contact structures, characterized in that at least one end portion comprises a peripherally protruding element starting from a base portion of the end portion configured to define a hollow part having a base at a surface of the base portion and is surrounded by the peripherally protruding element, said peripherally protruding element being configured to penetrate into the contact structures.

More particularly, the invention comprises the following additional and optional features, taken singularly or in combination if necessary.

According to another aspect of the invention, the peripherally protruding element may extend continuously at the entire circumference of the end portion of the contact probe.

The peripherally protruding element may in particular extend discontinuously at a circumference of the end portion of the contact probe and comprise a plurality of single protruding elements.

According to this aspect of the invention, the single protruding elements may be formed at side walls of the end portion of the contact probe.

In particular, the single protruding elements may be formed at edges of the end portion of the contact probe.

The single protruding elements may be L-shaped and formed at edges and so as to extend along contiguous walls of the end portion of the contact probe.

According to another aspect of the invention, the peripherally protruding element may comprise a plurality of single protruding elements formed at side walls of the end portion of the contact probe and/or a plurality of single protruding elements formed at edges of the end portion of the contact probe and/or a plurality of single protruding L-shaped elements and formed at edges and so as to extend along contiguous walls of the end portion of the contact probe.

Furthermore, according to another aspect of the invention, the end portion may be made of only one material, preferably a metallic material.

Alternatively, the end portion may be made by a multilayer made up of a plurality of conductive layers, of a same metallic material or of different metallic materials.

According to another aspect of the invention, the conductive layers of the plurality of conductive layers may have different heights at the peripherally protruding element.

In particular, the conductive layers may have gradually increasing, respectively decreasing, heights in the direction of the hollow part.

According to a further aspect of the invention, at least one layer of the conductive layers may be made of a second conductive material having a higher hardness than a hardness of a first conductive material forming the remaining conductive layers of the end portion.

In particular, said at least one layer may protrude with respect to the remaining conductive layers of the end portion, for instance at a height having a value between 2 μm and 50 μm.

According to another aspect of the invention, the base of the hollow part of the end portion may have an irregular or not planar shape, comprising reliefs.

Furthermore, the peripherally protruding element may have a thickness varying between 5 μm and 30 μm.

Still according to another aspect of the invention, the peripherally protruding element may have a dimension along the longitudinal development axis varying between 10 μm and 200 μm, preferably equal to 15-80% of a dimension along said longitudinal development axis of the end portion.

Furthermore, the contact probe may have a squared section having side comprised between 10 μm and 80 μm.

According to another aspect of the invention, the end portion comprises, at the peripherally protruding element, at least one coating of a second conductive material having a higher hardness than a hardness of a first conductive material forming the end portion.

In particular, the first conductive material may be a metal or a metallic alloy selected from nickel or an alloy thereof, copper or an alloy thereof, palladium or an alloy thereof, cobalt or an alloy thereof and the second conductive material may be a metal or a metallic alloy selected from rhodium or an alloy thereof, platinum or an alloy thereof, iridium or a metallic alloy thereof.

Preferably, the first conductive material may be palladium-cobalt and the second conductive material may be rhodium.

According to another aspect of the invention, the coating may be arranged at the hollow part defined in the end portion by the peripherally protruding element.

Suitably, the contact probe may be chosen between a vertical probe or a pogo pin probe.

Furthermore, the end portion may be a contact tip configured to contact a contact structure of a device under test.

Said contact structure may be a three-dimensional contact structure, preferably a bump or a pillar, or a planar contact structure, preferably a contact pad possibly coated by an oxide or dirt layer.

The technical problem is also solved by a probe head for a testing apparatus of electronic devices comprising a plurality of contact probes made as above indicated.

The characteristics and advantages of the contact probe according to the invention will be apparent from the description, made hereinafter, of an embodiment thereof, given by indicative and non-limiting example, with reference to the accompanying drawings.

### BRIEF DESCRIPTION OF DRAWINGS

In such drawings:

FIG. 1 schematically shows a probe head with vertical probes made according to the prior art;

FIG. 2 schematically shows a vertical probe of the pogo pin type made according to the prior art;

FIG. 3 schematically shows an embodiment of a contact probe according to the present invention, in a partial perspective view;

FIGS. 4A-4D, 5A-5D, 6, 7A-7B, 8A-8B, 9A-9C, 10A-10C and 11A-11C schematically show perspective views of alternative embodiments of a contact probe according to the present invention; and

FIGS. 12A-12B and 13A-13B schematically show section views of further alternative embodiments of a contact probe according to the present invention.

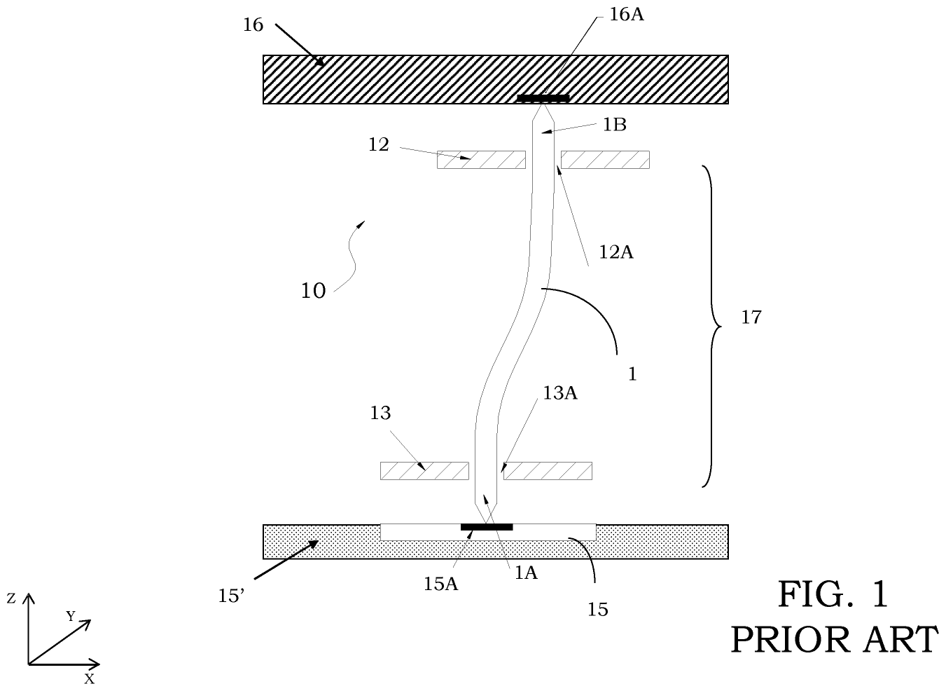

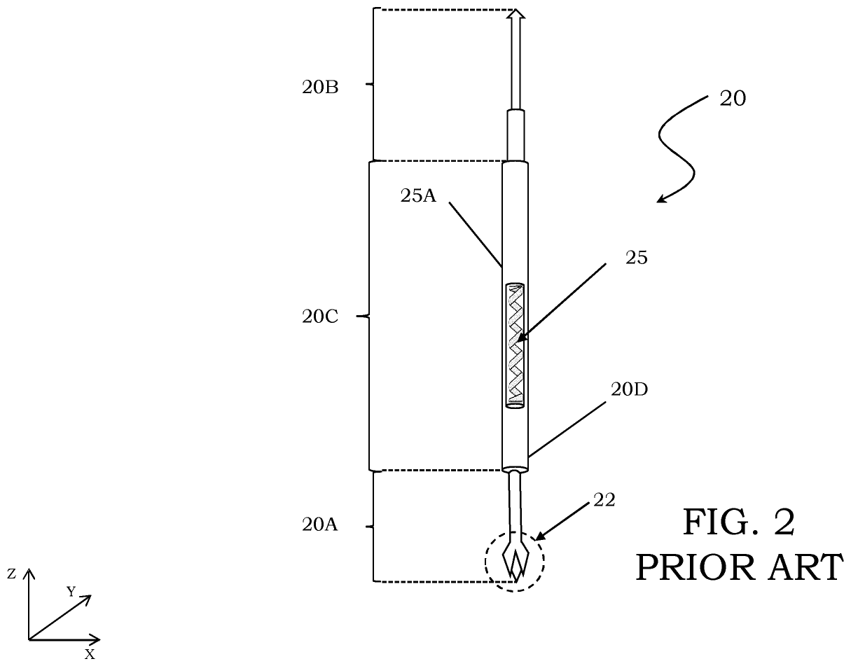

### MODES FOR CARRYING OUT THE INVENTION

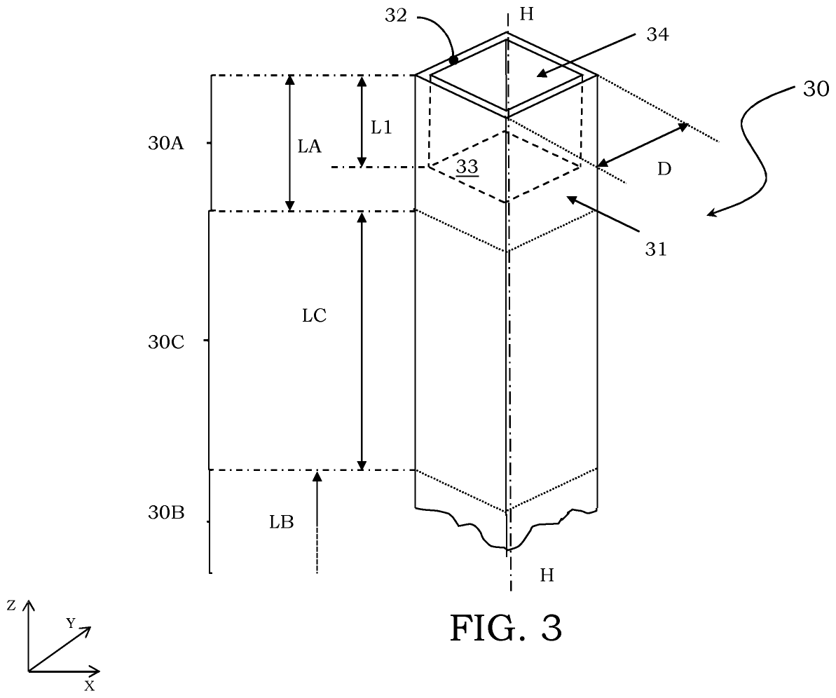

With reference to said Figures, and in particular to FIG. 3, a contact probe for a probe head for a testing apparatus of electronic devices integrated on a wafer, globally indicated by 30, is described.

It should be noted that the figures represent schematic views of the contact probe according to the invention and are not drawn to scale, but instead they are drawn so as to enhance the important features of the invention. In the figures, the different pieces are shown schematically and their shape may vary according to the desired application.

In particular, as seen in connection with the prior art, the contact probe 30 is used to make an electric connection between a device under test integrated on a wafer and a testing apparatus, not illustrated in the figure, and comprises a body portion 30C and a first end portion 30A and a second end portion 30B, respectively, which are usually indicated as a contact tip 30A configured to abut onto a contact structure of the device under test and a contact head 30B, configured to interface with a board configured to make the contact with the testing apparatus.

The contact probe 30 may be a vertical contact probe or a probe of the pogo pin type; substantially it extends along a longitudinal development axis HH arranged as the z axis of the local reference of FIG. 3 and preferably has, as in the illustrated example, a rectangular section.

In an embodiment, the body portion 30C has a longitudinal dimension LC, i.e. according to axis HH, comprised between 70 μm and 7000 μm, the contact tip 30A has a longitudinal dimension LA comprised between 12 μm and 1000 μm and the contact head 30B has a longitudinal dimension LB comprised between 20 μm and 2000 μm.

According to an aspect of the invention, at least one end portion of the contact probe 30, in particular the contact tip 30A comprises a base portion 31 and a peripherally protruding element 32 starting from said base portion 31. A hollow part 34 having a base 33 at an upper surface (according to the local reference of the Figure) of the base portion 31 and surrounded by the peripherally protruding element 32 is thus defined in the contact tip 30A.

In particular, the peripherally protruding element 32 extends starting from the base 33, i.e. from the base portion 31, according to the longitudinal development axis HH of the contact probe 30 in a direction opposite the body portion 30C, by a longitudinal dimension L1 comprised between 10 μm and 150 μm, i.e. equal to 15-85% of the longitudinal dimension LA of the contact tip 30A. Along said axis HH, i.e. according to the z axis direction of the local reference of the Figure, the body portion 30C, the base portion 31 and the peripherally protruding element 32 are thus arranged in succession and contiguously to each other. In a preferred embodiment, as illustrated in the figures, the contact probe 30 has a squared section having side D comprised between 10 μm and 80 μm.

The peripherally protruding element 32 realizes, indeed, the portion configured to contact a contact structure of a device under test, not represented. Such a contact structure may be a pad or contact pad, i.e. a substantially planar structure, or a three-dimensional structure, such as for instance a bump or a pillar.

Suitably, the peripherally protruding element 32 is able to penetrate, at least partially a three-dimensional contact structure, as well as a possible surface layer of a planar contact structure, such as an oxide or dirt layer covering a contact pad, thus ensuring the proper electric contact between the contact probe 30 and the device under test.

Substantially the contact tip 30A of the contact probe 30 comprising the peripherally protruding element 32 has a straw shape, in the example in the Figure a squared-section straw. Obviously it is possible to make the contact probe 30 and its contact tip 30A with a different section, such as a circular or rectangular section based on the needs.

Tests performed by the same Applicant highlighted an excellent penetrative ability of the contact tip 30A thanks to the peripherally protruding element 32, besides a reduced accumulation of material inside the hollow part 34 further to the testing operations, in particular of three-dimensional contact structures.

It is also worth stressing the fact that the peripherally protruding element 32 forming the real contact portion of the contact tip 30A has a constant section along the longitudinal axis HH, which is substantially kept unaltered over time even after cleaning operations made for instance by touch on abrasive cloth. Therefore, the contact probe 30 may be subjected to several cleaning operations, showing same performances, thus having a long useful life.

Suitably, according to the embodiment illustrated in FIG. 3, the peripherally protruding element 32 extends at the entire circumference or perimeter of the contact probe 30, in particular of its contact tip 30A, i.e. it runs continuously through all its side walls substantially in the shape of a ring, having a squared section according to the example illustrated in the Figure.

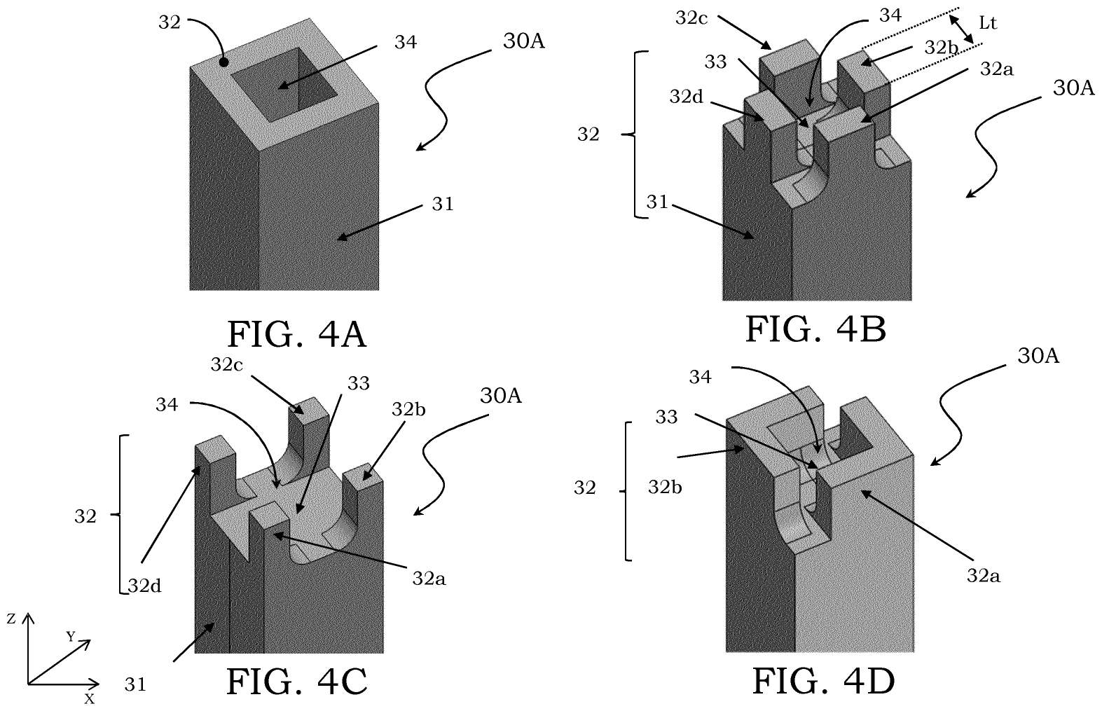

Several alternative embodiments of the peripherally protruding element 32 are possible, such as for instance illustrated in FIGS. 4A-4D, which only show the contact tip 30A of the contact probe 30.

In particular, according to a first embodiment illustrated in FIG. 4A, the peripherally protruding element 32 is in the shape of a continuous ring, which protrudes starting from the base portion 31 running through the entire circumference thereof and defines therein a hollow part 34 of the contact tip 30A, in a substantially correspondent manner to what has been illustrated in FIG. 3.

According to an alternative embodiment, schematically illustrated in FIG. 4B, the peripherally protruding element 32 is interrupted, in particular at corner portions. In this way, the peripherally protruding element 32 is made up of a plurality of single protruding elements 32a-32d arranged at the walls of the contact tip 30A of the contact probe 30 and extending just by a section of said walls, not comprising the corner portions. In a preferred embodiment, as illustrated in FIG. 4B, the single protruding elements 32a-32d extend at a central portion of the side walls of the contact tip 30A and have transversal dimensions Lt that are substantially equal to each other, thus forming a peripherally protruding element 32 that is substantially symmetric. Obviously it is possible to make the single protruding elements 32a-32d with different transversal dimensions and positioned in any way along the side walls of the contact tip 30A of the contact probe 30. It is also possible to provide for a peripherally protruding element 32 that comprises single protruding elements only at some but not all of the side walls of the contact tip 30A, possibly also at only two walls, which are contiguous or opposite each other.

According to a further alternative embodiment, schematically illustrated in FIG. 4C, the peripherally protruding element 32 is equally interrupted, in particular at central portions of the side walls of the contact tip 30A of the contact probe 30. In this way, the peripherally protruding element 32 is made up of a plurality of single protruding elements 32a-32d arranged at the edges of the contact tip 30A. In a preferred embodiment, as illustrated in FIG. 4C, the single protruding elements 32a-32d have a squared section of the same area. It is also possible to make the single protruding elements 32a-32d with sections different in shape or dimensions, for instance rectangular, or to provide for a peripherally protruding element 32 comprising single protruding elements only at some but not all of the edges of the contact tip 30A, possibly even at only two edges, that are contiguous and opposite each other.

Alternatively, as schematically illustrated in FIG. 4D, the interrupted peripherally protruding element 32 comprises single protruding L-shaped elements 32a-32b arranged at edges of the contact tip 30A of the contact probe 30. In the example of the Figure, the single protruding elements 32a e 32b are L-shaped having two arms of the same length and extending beyond the half of two contiguous side walls of the contact tip 30A, said elements being in the number of two and arranged at opposite edges. It is also possible to make the single protruding elements 32a-32b in the L-shape with two arms of different lengths or to provide for a number of single protruding L-shaped elements greater than two, for instance four single protruding L-shaped elements at the four edges of the contact tip 30A of the contact probe 30.

Moreover, it is possible to provide for a combination of the different alternative embodiments of the interrupted peripherally protruding element 32 illustrated in FIGS. 4B-4D, for instance formed by single protruding elements arranged both at the side walls of the contact tip 30A and at the edges thereof, by combining the alternative embodiments illustrated in FIGS. 4B and 4C, in the shape of battlements of a castle. It is also possible to make the peripherally protruding element 32 so as to comprise single protruding elements both at the side walls of the contact tip 30A and as L-shaped elements at the edges thereof by combining the alternative embodiments illustrated in FIGS. 4B and 4D. The interrupted peripherally protruding element 32 may also comprise some protruding elements arranged at the side walls, some protruding elements arranged at the edges, and some protruding elements arranged at the edges being L-shaped elements, duly sized in order to fit within the perimeter of the contact tip 30A, so as to combine the embodiments of FIGS. 4B, 4C and 4D.

Other alternative embodiments with a different number of single protruding elements, in a symmetrical or asymmetrical shape or arrangement, may be provided, anyway formed at a peripheral portion of the contact tip 30A of the contact probe 30, so as to form the interrupted peripherally protruding element 32.

It is pointed out that the peripherally protruding element 32 in the different illustrated alternative embodiments, even when interrupted, is able to define therein a hollow part 34 of the contact tip 30A, which extends up to a base 33 corresponding to an upper surface of the base portion 31 of the contact tip 30A.

The contact tip 30A of the contact probe 30 illustrated in FIGS. 4A-4B is made of only one material. In particular, the contact tip 30A is made of a first conductive material that is metal or a metallic alloy and may be for instance nickel or an alloy thereof, such as nickel-manganese, nickel-cobalt or nickel-tungsten alloys, copper or an alloy thereof, palladium or an alloy thereof, cobalt or an alloy thereof. In a preferred embodiment of the invention, the first conductive material is palladium-cobalt.

In a preferred embodiment, the contact tip 30A is made as a single piece and of the same material as the body portion 30C of the contact probe 30. It is also possible to provide for a coating material of the contact tip 30A, such as a covering layer made of a low internal stress conductive alloy, such as a nickel alloy, able to improve the mechanical performances of the contact tip 30A of the contact probe 30.

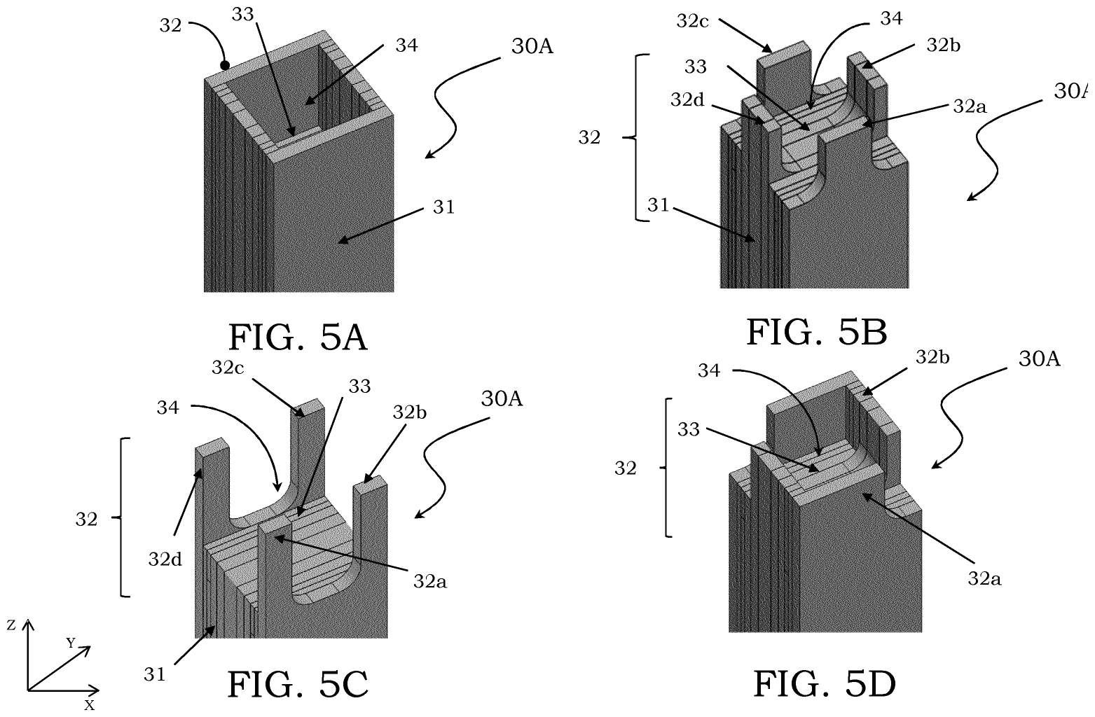

The contact probe 30 may also be formed by means of a multilayer made up of a plurality of conductive layers, of the same or different materials. In this case, the contact tip 30A is also formed by a multilayer, as schematically illustrated in FIGS. 5A-5D, corresponding to the different alternative embodiments of the contact tip 30A of FIGS. 4A-4D and in particular comprising a continuous peripherally protruding element 32 (FIG. 5A) or an interrupted peripherally protruding element 32, of the type comprising single protruding elements 32a-32d arranged at the side walls of the contact tip 30A (FIG. 5B), or comprising single protruding elements 32a-32d arranged at the edges of the contact tip 30A (FIG. 5C), or comprising single L-shaped protruding elements 32a-32b (FIG. 5D). It is pointed out that, in this case, the base 33 also comprises a plurality of layers, as illustrated in FIGS. 5A-5D, said base 33 being substantially planar.

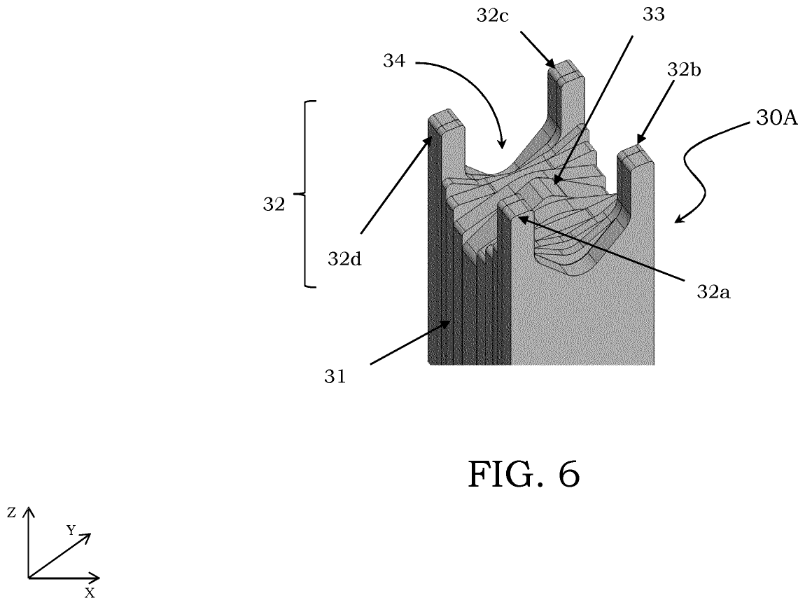

It is also possible to make the base 33 with an irregular or not planar shape, for instance comprising reliefs, as schematically illustrated in FIG. 6. Though in said FIG. 6, the contact tip 30A, and thus the base 33 as well, is made starting from a multilayer, it is also possible to obtain the irregular or not planar trend with reliefs of the base 33 even when the contact tip 30A is made of only one material.

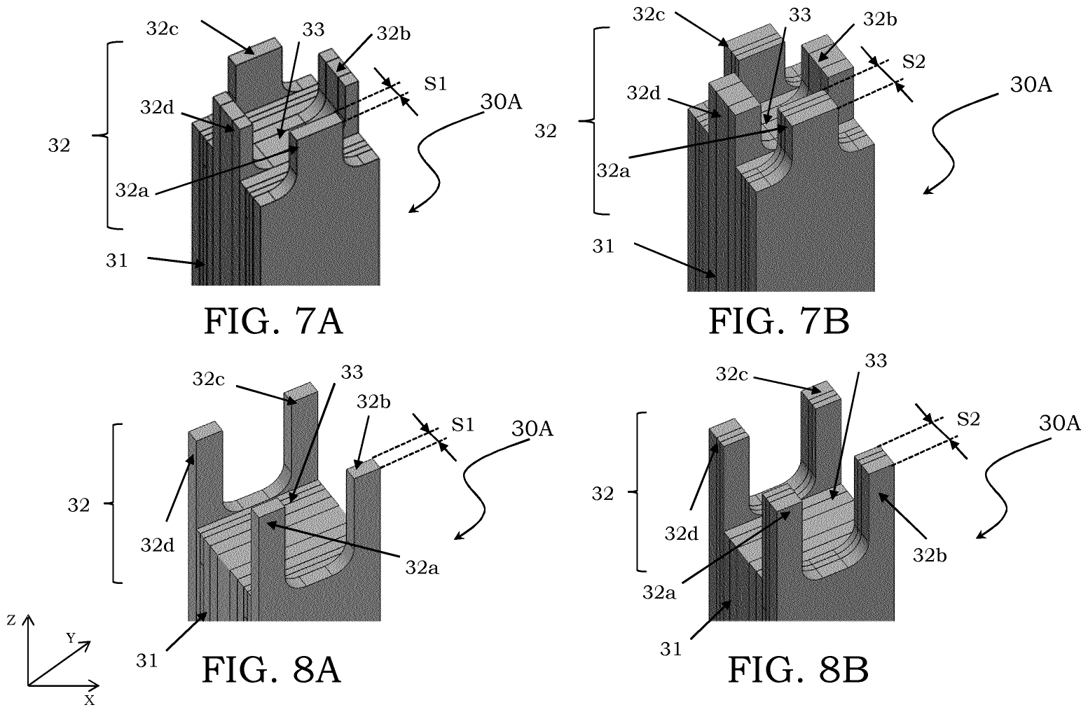

Advantageously according to the present invention, it is also possible to make the peripherally protruding element 32, continuous or interrupted, with different thicknesses S1, S2 as illustrated in FIGS. 7A-7B for an interrupted peripherally protruding element 32 comprising single protruding elements 32a-32d arranged at the side walls of the contact tip 30A of the contact probe 30 and in FIGS. 8A-8B for an interrupted peripherally protruding element 32 comprising single protruding elements 32a-32d arranged at edges of the contact tip 30A of the contact probe 30. In the examples illustrated in the figures, the contact tips 30A are preferably made of a multilayer, one or more layers also forming the single protruding elements 32a-32d.

More particularly, the peripherally protruding element 32 and in particular its single protruding elements 32a-32d may have a thickness varying between 5 μm and 30 μm.

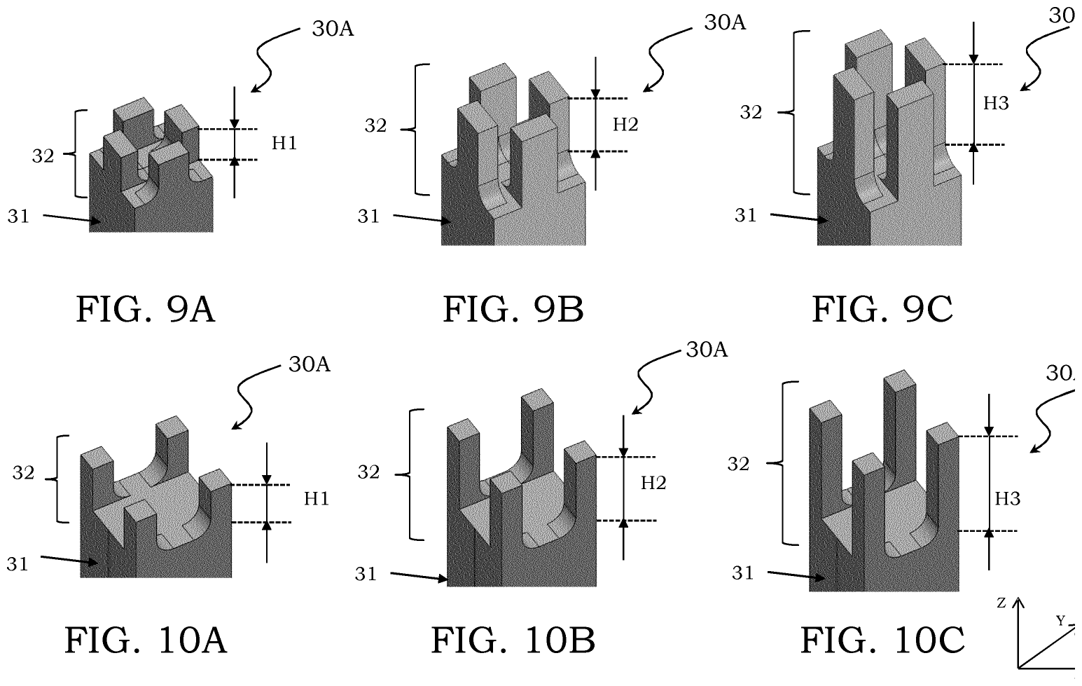

Further advantageously, it is possible to make the peripherally protruding element 32, continuous or interrupted, with different heights H1-H3 starting from the base portion 31, as illustrated in FIGS. 9A-9C for an interrupted peripherally protruding element 32 comprising single protruding elements 32a-32d arranged at the side walls of the contact tip 30A of the contact probe 30 and in FIGS. 10A-10C for an interrupted peripherally protruding element 32 comprising single protruding elements 32a-32d arranged at edges of the contact tip 30A of the contact probe 30.

As previously seen for the continuous peripherally protruding element 32, the interrupted peripherally protruding element 32 and in particular its single protruding elements 32a-32d may also have heights varying between 10 μm and 200 μm.

It is also pointed out how the possibility of making a contact tip 30A with a peripherally protruding element 32 having a considerable height, as illustrated for instance in FIGS. 9C and 10C, allows ensuring that said contact tip 30A may be subjected to a high number of cleaning operations, in particular by touch on abrasive cloth, before risking to modify its section at the area in contact with the three-dimensional or planar contact structure of the device under test, thus ensuring a prolonged useful life to the contact probe 30.

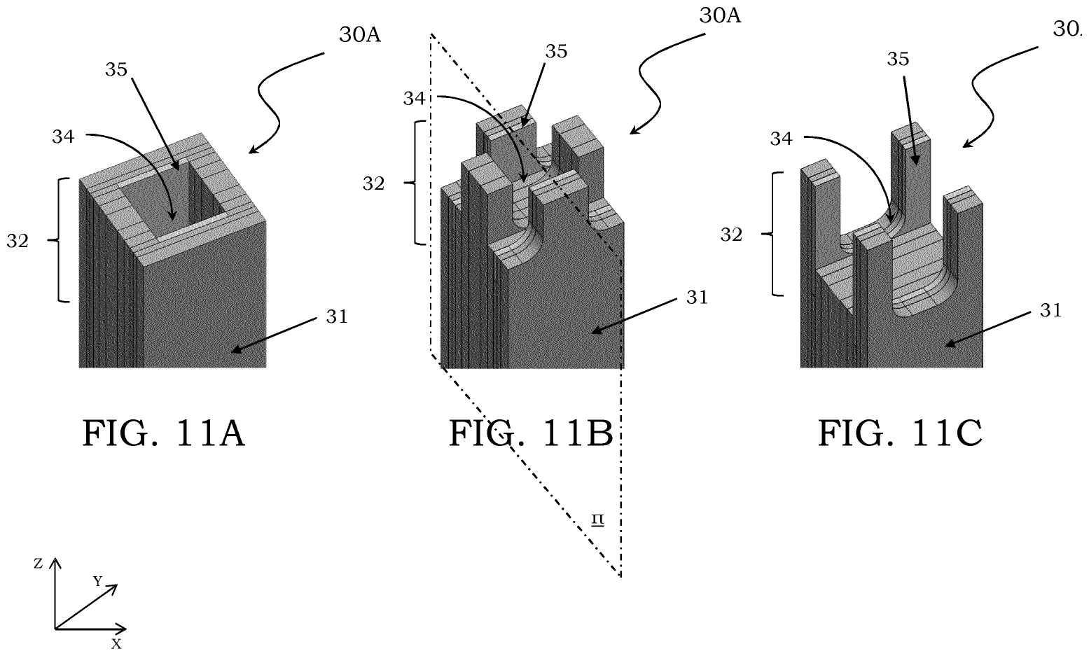

Finally, according to a preferred embodiment of the invention, the contact tip 30A comprises, at the peripherally protruding element 32, at least one coating 35 of a second conductive material having a higher hardness than the hardness of the first conductive material that forms the contact probe 30 and thus the contact tip 30A, as schematically illustrated in FIGS. 11A-11C, for the alternative embodiments with a continuous peripherally protruding element 32 (FIG. 11A) or with an interrupted peripherally protruding element 32, in particular comprising single protruding elements 32a-32d arranged at the side walls of the contact tip 30A of the contact probe 30 (FIG. 11B) and comprising single protruding elements 32a-32d arranged at edges of the contact tip 30A of the contact probe 30 (FIG. 11C).

More particularly, the second conductive material is a metal or a metallic alloy and may be rhodium or an alloy thereof, platinum or an alloy thereof, iridium or an alloy thereof, for instance a palladium-cobalt alloy, a palladium-nickel alloy or a nickel-phosphorus alloy. In a preferred embodiment of the invention, the second conductive material is rhodium.

Suitably, said coating 35 is arranged at the hollow part 34 defined in the contact tip 30A by the continuous or interrupted peripherally protruding element 32.

In this way, the coating 35 of high hardness material is able, in addition to delaying the consumption of the peripherally protruding element 32 and thus to extending the working life of the contact probe 30, to reduce the accumulation of material inside the hollow part 34 during the penetration of the contact tip 30A into three-dimensional or planar contact structures, in particular in surface layers of contact pads.

According to an alternative embodiment, the contact probe 30, and in particular the contact tip 30A, made by a multilayer comprising a plurality of conductive layers 36, of the same or different materials, may have layers of different heights at the peripherally protruding element 32, with increasing or decreasing values in the direction of the hollow part 34.

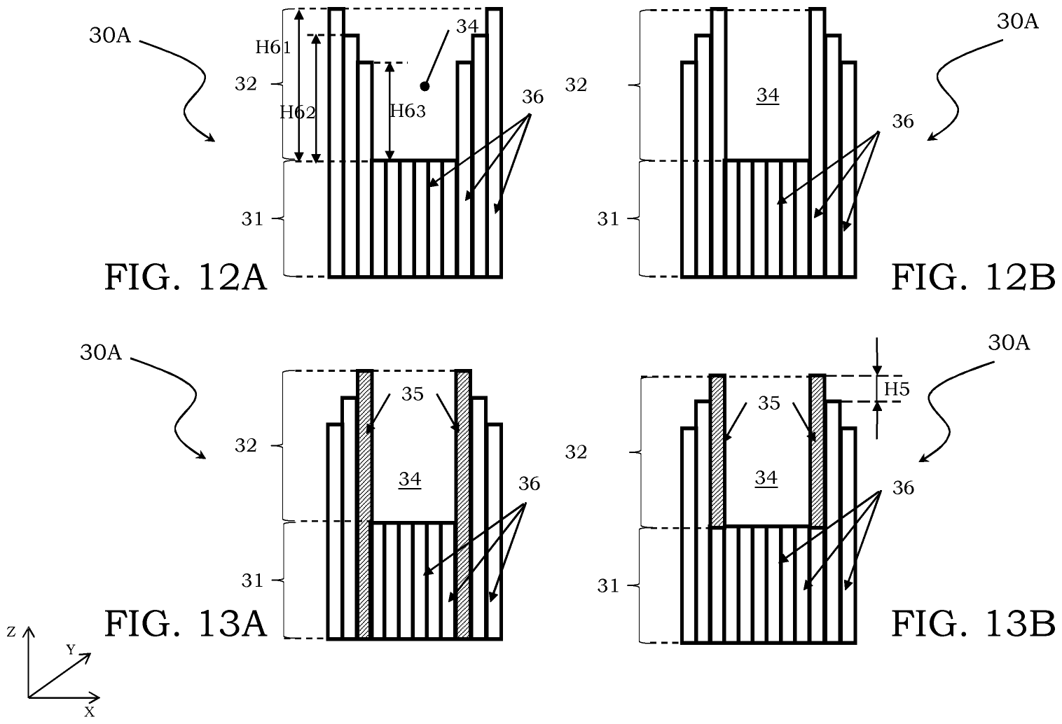

More particularly, in the sections illustrated in FIGS. 12A and 12B, corresponding to a section at a plane n arranged along the longitudinal development axis HH of the probe 30 and passing through the center of two single protruding elements arranged on opposite walls of the contact tip 30A, as indicated for instance in FIG. 11B, each single protruding element comprises a plurality, in the example three conductive layers 36 of different heights, H6₁, H6₂ e H6₃ respectively, which may have a gradually decreasing value starting from the outer perimeter towards the hollow part 34, as illustrated in FIG. 12A, or a gradually increasing value, as illustrated in FIG. 12B.

It is pointed out that this alternative embodiment of the contact tip 30A of the contact probe 30 according to the present invention increases the penetrative ability of its peripherally protruding element 32, in particular of the single protruding elements 32a-32d and decreases the quantity of unwanted residual material that accumulates on said contact tip 30A during the testing operations, in particular on contact three-dimensional structures.

It is possible to further improve the penetrative ability of the contact tip 30A and to reduce possible accumulated material by making at least the layer of greater height of its peripherally protruding element 32, in particular of the single protruding elements 32a-32d, by means of the second conductive material with high hardness, in particular rhodium, thus forming the coating 35 arranged at the hollow part 34, i.e. in the case of conductive layers having gradually increasing heights, as illustrated in FIGS. 13A and 13B.

More particularly, the coating layer 35 may develop along the whole contact tip 30A, as illustrated in FIG. 13A (and possibly also continue in the rest of the contact probe 30) or be only formed at the hollow part 34, as illustrated in FIG. 13B.

Preferably, the coating layer 35 in this case is made so as to protrude with respect to the other layers forming the peripherally protruding element 32, or the single protruding elements 32a-32d, by a height H6 value varying from 2 μm to 50 μm.

Suitably, the contact tip 30A may be used to make an end portion of a vertical contact probe or of a probe of the pogo pin type.

Essentially, the contact probe having a contact tip equipped with a peripherally protruding element ensures a proper contact with contact structures of a device under test, in particular three-dimensional contact structures such as bumps or pillars, but also planar contact structures such as pads, in particular when covered with oxide or dirt layers which the contact tip must suitably penetrate.

Advantageously, the shapes of the contact tips comprising said peripherally protruding element have a constant section along a longitudinal development axis of the contact probe itself and ensures constant performances thereof also further to numerous testing and cleaning operations. Suitably, said peripherally protruding elements may have dimensions adapted to make a tip “on consumption” and are particularly advantageous to make contact tips of the so-called pogo pin probes.

It is further pointed out that the contact tips comprising the continuous or discontinuous peripherally protruding element may also further be made of multilayers of materials suitable to maximize the penetration ability of the tip itself, as well as to ensure a minimization of material retention, in particular further to the penetration into the three-dimensional contact structures or in possible oxide layers being on planar contact structures, such as the pads of the device under test. Suitably, said contact tips may also be equipped, at the peripherally protruding element, with a coating of a second conductive material having higher hardness than a hardness of the first conductive material forming the contact probe and thus the contact tip, preferably arranged at the hollow part defined in the contact tip, said coating delaying the consumption of the peripherally protruding element and thus extending the useful life of the contact probe, meanwhile allowing to further reduce the accumulation of material inside the hollow part of the contact tip during its penetration into contact structures of the device under test.

Suitably, the peripherally protruding element, or its single protruding elements, may be made by a plurality of conductive layers of different heights, the layer having greater height being preferably made of the second conductive material and being arranged at the hollow part, so as to increase the penetrative ability of said peripherally protruding element or of the single protruding elements that make it up, while limiting its consumption over time and reducing the accumulation of material inside the hollow part of the contact tip thus obtained.

Obviously, a person skilled in the art, in order to satisfy contingent and specific requirements, may make to the contact probe above described numerous modifications and variations, all included in the scope of protection of the invention as defined by the following claims.

For instance, it is possible to combine different ones of the illustrated embodiments to get closer and closer to a crown shape of the widely used pogo pin tips, while ensuring a constant section also further to touch on abrasive cloths, as well as a reduction of any material retained within the contact tip following testing of the device under test. In particular, it would be possible to make a contact tip equipped with a peripherally protruding element comprising single protruding elements positioned both at side walls of the contact probe and at edges thereof, as well as a base equipped with reliefs.

Furthermore, it is possible to make the contact probe by means of a multilayer and to make the contact tip of only one material or vice versa.

Finally, it is possible to use one of the embodiments above illustrated to make the contact head of the probe, i.e. the end portion configured to contact a space transformer or generically a board for the connection with a testing apparatus.

1. A contact probe for a probe head for a test equipment of electronic devices comprising:
a first end portion and a second end portion configured to realize a contact with suitable contact structures;
a body portion extended along a longitudinal development axis between respective the first and second end portions;
wherein the first end portion comprises:
a base portion;
a peripherally protruding element protruding from the base portion; and
a hollow part having a base at a surface of the base portion and being surrounded by the peripherally protruding element
and wherein the peripherally protruding element is configured to penetrate into the contact structures.

2. The contact probe of claim 1, wherein the peripherally protruding element extends continuously at the entire circumference of the end portion of the contact probe.

3. The contact probe of claim 1, wherein the peripherally protruding element extends discontinuously at a circumference of the first end portion of the contact probe and comprises a plurality of single protruding elements.

4. The contact probe of claim 3, wherein the single protruding elements are formed at side walls of the first end portion of the contact probe.

5. The contact probe of claim 3, wherein the single protruding elements are formed at the edges of the first end portion of the contact probe.

6. The contact probe of claim 3, wherein the single protruding elements are L-shaped and are formed at edges and so as to extend along contiguous walls of the first end portion of the contact probe.

7. The contact probe of claim 3, wherein the peripherally protruding element comprises one or more between: a plurality of single protruding elements formed at side walls of the first end portion of the contact probe; a plurality of single protruding elements formed at edges of the first end portion of the contact probe; a plurality of single L-shaped protruding elements and formed at edges and so as to extend along contiguous walls of the first end portion of the contact probe.

8. (canceled)

9. (canceled)

10. The contact probe according to claim 1, wherein the first end portion is made by a multilayer comprising a plurality of conductive layers.

11. The contact probe of claim 10, wherein the conductive layers of the plurality of conductive layers have different heights in correspondence of the peripherally protruding element.

12. The contact probe of claim 11, wherein the conductive layers have gradually increasing heights respectively decreasing in the direction of the hollow part.

13. The contact probe of claim 11, wherein at least one layer of the conductive layers is made of a second conductive material having higher hardness than the hardness of a first conductive material forming the remaining conductive layers of the first end portion.

14. The contact probe of claim 13, wherein the at least one layer protrudes with respect to the remaining conductive layers of the first end portion.

15. (canceled)

16. The contact probe of claim 1, wherein the base of the hollow part of the first end portion has an irregular or not planar shape, comprising reliefs.

17. (canceled)

18. (canceled)

19. (canceled)

20. (canceled)

21. The contact probe according to claim 9, wherein the first end portion is formed by a first conductive material and comprises, in correspondence of the peripherally protruding element, at least one coating of a second conductive material having higher hardness than a hardness of the first conductive material.

22. The contact probe of claim 21, wherein the first conductive material is selected from the group consisting of a metal, a metallic alloy selected from nickel, nickel alloy, copper, copper alloy, palladium, palladium alloy, cobalt, cobalt alloy and in that said second conductive material is chosen between a metal, a metallic alloy selected from rhodium, rhodium alloy, platinum, platinum alloy, iridium, iridium alloy.

23. The contact probe of claim 22, wherein the coating is arranged at the hollow part defined at the first end portion by the peripherally protruding element.

24. (canceled)

25. The contact probe of claim 1, wherein the first end portion is a contact tip configured to contact a contact structure of a device under test.

26. The contact probe of claim 1, wherein the contact structure is a contact three-dimensional structure selected from the group consisting of: a bump, a pillar, a contact planar structure, a contact pad, a contact pad coated by a layer of oxide, a contact pad coated by a layer of dirt.

27. (canceled)

28. A probe head for a test equipment of electronic devices wherein it comprises a plurality of contact probes, each contact probe comprising:
a first end portion and a second end portion configured to realize a contact with suitable contact structures;
a body portion extended along a longitudinal development axis between respective the first and second end portions;
wherein the first end portion comprises:
a base portion;
a peripherally protruding element protruding from the base portion; and
a hollow part having a base at a surface of the base portion and being surrounded by the peripherally protruding element
and wherein the peripherally protruding element is configured to penetrate into the contact structures.

29. The probe head of claim 28, wherein the peripherally protruding element is chosen between: a peripherally protruding element extending continuously at the entire circumference of the end portion of the contact probe; a peripherally protruding element extending discontinuously at a circumference of the first end portion of the contact probe and comprising a plurality of single protruding elements, the single protruding elements being formed at side walls of the first end portion of the contact probe; a peripherally protruding element extending discontinuously at a circumference of the first end portion of the contact probe and comprising a plurality of single protruding elements, the single protruding elements being formed at the edges of the first end portion of the contact probe; a peripherally protruding element extending discontinuously at a circumference of the first end portion of the contact probe and comprising a plurality of single protruding elements, the single protruding elements being L-shaped and formed at edges, so as to extend along contiguous walls of the first end portion of the contact probe; a peripherally protruding element comprising one or more between: a plurality of single protruding elements formed at side walls of the first end portion of the contact probe; a plurality of single protruding elements formed at edges of the first end portion of the contact probe; a plurality of single L-shaped protruding elements and formed at edges and so as to extend along contiguous walls of the first end portion of the contact probe.

30. The probe head of claim 28, wherein the first end portion is made by a multilayer comprising a plurality of conductive layers chosen between: a plurality of conductive layers having different heights in correspondence of the peripherally protruding element; a plurality of conductive layers have gradually increasing heights respectively decreasing in the direction of the hollow part; a plurality of conductive layers with at least one layer being made of a second conductive material having higher hardness than the hardness of a first conductive material forming the remaining conductive layers of the first end portion; a plurality of conductive layers with at least one layer being made of a second conductive material having higher hardness than the hardness of a first conductive material forming the remaining conductive layers of the first end portion and protruding with respect to the remaining conductive layers of the first end portion.

31. The probe head of claim 28, wherein the base of the hollow part of the first end portion has an irregular or not planar shape, comprising reliefs.

32. The probe head of claim 28, wherein the first end portion is formed by a first conductive material and comprises, in correspondence of the peripherally protruding element, at least one coating of a second conductive material having higher hardness than a hardness of the first conductive material, the first conductive material being chosen between a metal, a metallic alloy selected from nickel, nickel alloy, copper, copper alloy, palladium, palladium alloy, cobalt, cobalt alloy and in that said second conductive material is chosen between a metal, a metallic alloy selected from rhodium, rhodium alloy, platinum, platinum alloy, iridium, iridium alloy.

33. The probe head of claim 28, wherein the first end portion is a contact tip configured to contact a contact structure of a device under test.

34. The probe head of claim 28, wherein the contact structure is a contact three-dimensional structure chosen between a bump, a pillar, a contact planar structure, a contact pad, a contact pad coated by a layer of oxide, a contact pad coated by a layer of dirt.
